(19) United States
(12) Patent Application Publication
(10) Pub. No.: US 2016/0204158 A1
(43) Pub. Date: Jul. 14, 2016

(54) COMPLEMENTARY METAL OXIDE SEMICONDUCTOR IMAGE SENSOR DEVICE AND METHOD OF FORMING THE SAME

(71) Applicant: UNITED MICROELECTRONICS CORP., Hsin-Chu City (TW)

(72) Inventors: Chien-En Hsu, Hsinchu County (TW); Chen Jie Gu, Zhuji (CN)

(21) Appl. No.: 14/595,167

(22) Filed: Jan. 12, 2015

(51) Int. Cl. H01L 27/146

(52) U.S. Cl. CPC H01L 27/14643; H01L 27/1463; H01L 27/14636; H01L 27/14689

(57) ABSTRACT

The present invention relates to a CMOS image sensor device and a method of forming the same. The CMOS image sensor device includes a substrate, a deep trench isolation (DTI), a photodiode, an electrode and an interface region. The DTI and the photodiode are both disposed in the substrate. The electrode is disposed on the DTI. The interface region is formed adjacent to the DTI.

### BACKGROUND OF THE INVENTION

1. Field of the Invention

The present invention relates to a complementary metal oxide semiconductor (CMOS) image sensor device and a method of forming the same, and more particularly to a CMOS image sensor device having deep trench isolation (DTI) and a method of forming the same.

2. Description of the Prior Art

Complementary metal-oxide-semiconductor (CMOS) image sensor device has widely been used in a variety of applications, for example, digital cameras and mobile phone cameras. The CMOS image sensor device generally includes a photodiode for sensing light. Light currents from the photodiode induced by light represents a signal, whereas dark current generated from the photodiode in the absence of light represents noise. The photodiode processes signal data by using the value of the signal-to-noise ratio. Excessive dark current lowers the dynamic range of the CMOS image sensor device because there is insufficient ability to distinguish between the light and dark currents. Generally, dark current is related to surface defects or plasma damage, which may usually result from the forming process thereof. For example, after forming the photodiode of a CMOS image sensor device, the surface of the photodiode tends to be damaged during the plasma etching process, thereby leading to dark current.

Thus, minimizing dark current in the photodiode is a key device optimization step in forming the CMOS image sensor device.

### SUMMARY OF THE INVENTION

It is one of the primary objectives of the present invention to provide a CMOS image sensor device, which includes DPI to function as a depleting transistor, thereby improving the dark current issues.

It is another one of the primary objectives of the present invention to provide a method of forming a CMOS image sensor device, which can efficiently improve the dark current issues.

To achieve the purpose described above, the present invention provides a CMOS image sensor device, including a substrate; a deep trench isolation (DTI); a photodiode; an electrode and an interface region. The DTI and the photodiode are both disposed in the substrate. The electrode is disposed on the DTI. The interface region is formed adjacent to the DTI.

To achieve the purpose described above, the present invention provides a method of forming a CMOS image sensor device, including following steps. First of all, a substrate is provided. Next, a DTI and a photodiode are formed in the substrate, respectively. Then, an electrode is formed on the DTI. Finally, an interface region is formed adjacent to the DTI.

In the present invention, a CMOS image sensor device is formed to include a deep trench isolation which may also function as a depletion transistor. Thus, through controlling the voltage bias applied to the deep trench isolation, the deep trench isolation may optionally perform a hole accumulation layer or a depletion layer accordingly, and therefore, the dark currents resulting from the defected surface, as well as image lag and white pixel issues may be all obviously reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are schematic diagrams illustrating a method of forming a CMOS image sensor device in accordance with one embodiment of the present invention.

FIG. 4 to FIG. 5 are a schematic diagrams illustrating functions of the CMOS image sensor device in accordance with one embodiment of the present invention.

FIG. 6 to FIG. 7 are schematic diagrams illustrating a preferably layout of a CMOS image sensor device in accordance with one embodiment of the present invention.

### DETAILED DESCRIPTION

In the following description, numerous specific details, as well as accompanying drawings, are given to provide a thorough understanding of the invention. It will, however, be apparent to one skilled in the art that the invention may be practiced without these specific details.

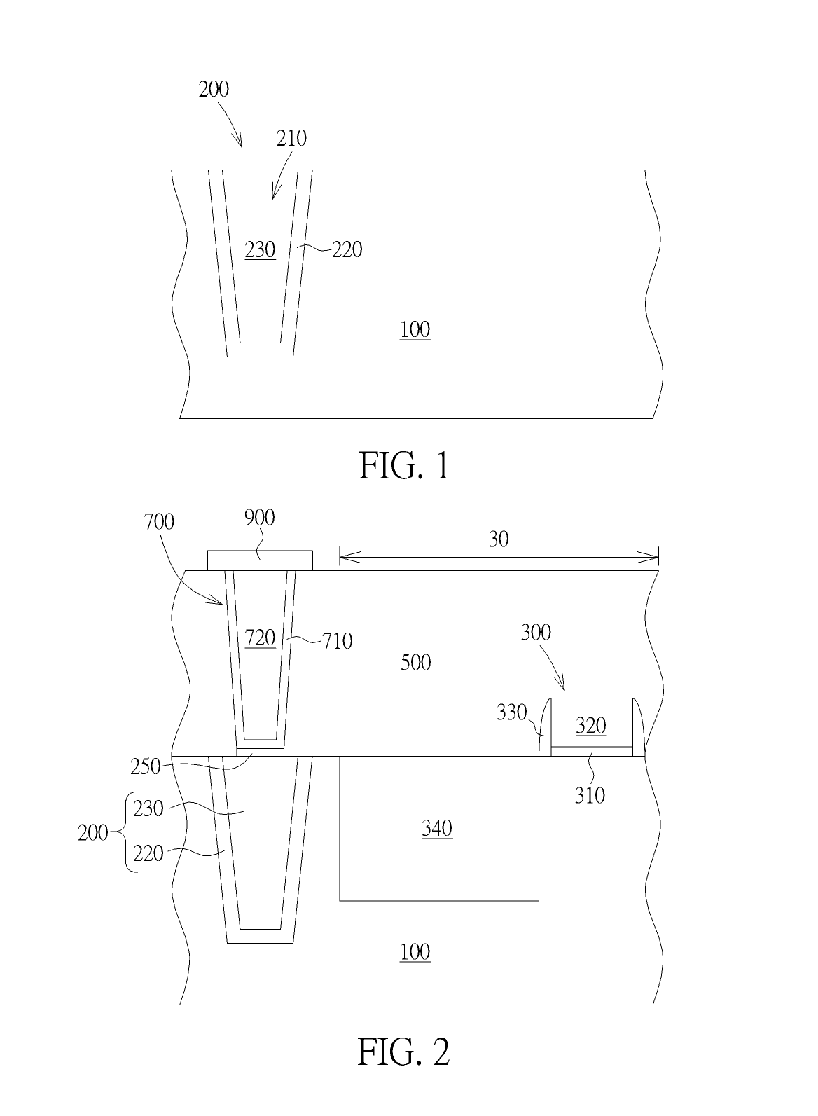

Please refer to FIGS. 1-3 which are schematic drawings illustrating the method of forming a CMOS image sensor device according to one embodiment in the present invention. Firstly, as shown in FIG. 1, a substrate 100 having a first conductive type (for example P type), such as a silicon substrate, is provided and a deep trench isolation 200 is formed in the substrate 100. Precisely speaking, the deep trench isolation 200 of the present embodiment may be formed through firstly providing a patterned hard mask layer (not shown in the drawings), for example a composite layer including a pad oxide layer and a silicon nitride layer, on a top surface of the substrate 100 for defining a deep trench 210, and then performing an etch process, such as a dry etching process, to transfer the pattern of the patterned hard mask layer to the substrate 100, thereby forming the deep trench 210 in the substrate 100. In one embodiment, the deep trench 210 has a depth in a range of 3000-4000 angstroms, but not limited thereto.

Following these, a dielectric layer 220 and a conductive layer 230 are then formed respectively in the deep trench 210, thereby forming the deep trench isolation 200 of the present embodiment. Wherein, the dielectric layer 220 may include high quality silicon oxide, and the conductive layer 230 may include metal, such as tungsten (W), aluminum (Al) or cooper (Cu); or polysilicon, and has the same conductive type (such as P type) to the substrate 100, but not limited thereto. For example, the dielectric layer 220 may be formed on an inner surface of the deep trench by directly performing a thermal oxidation process to obtain a substantially even surface, and the conductive layer 230 is then formed on the dielectric layer 210 by filling the deep trench 210 with a conductive material. However, people in the art shall easy to realized that the dielectric layer and the conductive layer of the present invention are not limited to be formed through the above mentioned processes, for example, in another embodiment, the dielectric layer and the conductive layer may also be formed through entirely depositing a dielectric material layer and a conductive material layer firstly via a chemical vapor deposition (CVD) or a physical vapor deposition (PVD) in the deep trench, and then removing the dielectric material layer and the conductive material layer outside the deep trench through a planarization process, such as a chemical mechanical polishing (CMP). Also, in another embodiment of the present invention, a doped region (not shown in the drawings) having the same conductive type (for example P type) to the substrate 100 may be optionally formed on an inner surface of the deep trench 210 before the dielectric layer 220 is formed.

Then, as shown in FIG. 2, after the deep trench isolation 200 is formed, an active area 30 having a photodiode 340 may be defined according. The photodiode 340 is a deep doped region (preferably having a second conductive type which is different from that of the substrate 100, such as n type) for example being formed through an ion implantation process in the active region 30. In the present embodiment, the photodiode 340 maybe formed right adjacent to a gate structure 300 in the substrate 100, such that the photodiode 340 may be adjacent to but not directly contact the deep trench isolation 200, as shown in FIG. 2. On the other hand, the gate structure 300 includes a gate dielectric layer 310, a gate electrode 320 and a spacer 330 surrounding the gate electrode 320, and which is formed by a conventional semiconductor process for forming a gate which will not be further detail herein.

Furthermore, please view further in FIG. 2, after the photodiode 340 is formed, an ohmic contact structure 700 is then formed over the deep trench isolation 200, thereby electrically connecting the deep trench isolation 200 to an electrode 900. Precisely, the ohmic contact structure 700 includes a barrier layer 710 and a conductive layer 720, and which may be formed by firstly providing an interlayer dielectric layer 500 on the substrate 100 entirely, forming a contact hole (not shown in the drawings) in the interlayer dielectric layer 500 in alignment with the deep trench isolation 200, and sequentially forming the barrier layer 710, such as a single layer or a multilayer structure made of titanium (Ti), tantalum (Ta), tantalum nitride (TaN), titanium nitride (TiN) or other suitable materials, and the conductive layer 720, such as tungsten, aluminum or copper, but not limited thereto. In an preferably embodiment, before the ohmic contact 700 is formed, a silicide layer 250 is previously formed on a surface of the conductive layer 230 of the deep trench isolation 200, for providing preferably electrically connection between the conductive layer 230 and the ohmic contact 700. However, the silicide layer may also be omitted in another embodiment of the present invention. Furthermore, in another embodiment, before the interlayer dielectric layer 500 is formed, another dielectric layer (not shown in the drawings) may be formed previously on the deep trench isolation 200 for example integrated into a step of forming the gate dielectric layer in a conventional semiconductor process, and thus that, an opening may be further to penetrate through the interlayer dielectric layer 500 and the dielectric layer when forming the ohmic contact 700.

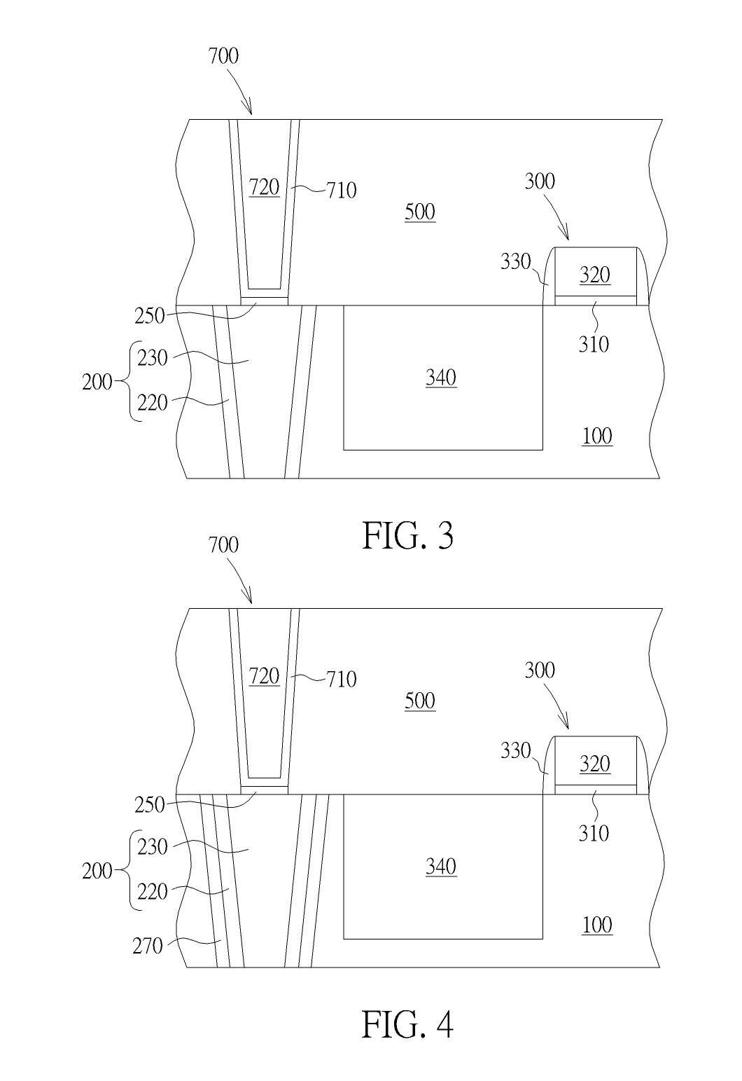

Next, as shown in FIG. 3, after completely forming an interconnection system (not shown in the drawing) on the top surface of the substrate 100, a thinning process is carried out from a bottom surface which is opposite to the top surface of the substrate 100 to thin the substrate 100, thereby exposing a portion of the dielectric layer 220 and a portion of the conductive layer 230 from the bottom surface of the substrate 100. In other words, the deep trench isolation 200 may be penetrates through both from a top surface and a bottom surface of the substrate 100. Following these steps, the CMOS image sensor device of the present embodiment is formed accordingly, and which is configured as a backside illumination (BSI) sensor device. Also, through connecting to the electrode 900, voltage bias may be applied to the deep trench isolation 200 of the CMOS image sensor device, such that the deep trench isolation 200 may function as a depletion transistor, thereby improve the transmission of the electron in the photodiode 340. In this way, the photodiode 340 of the present embodiment may be formed to include relative heavier doped condition (preferably relative heavier n type dopant), such as 2×10¹² and 2×10¹³ ions/cm², so as to improve image lag issues.

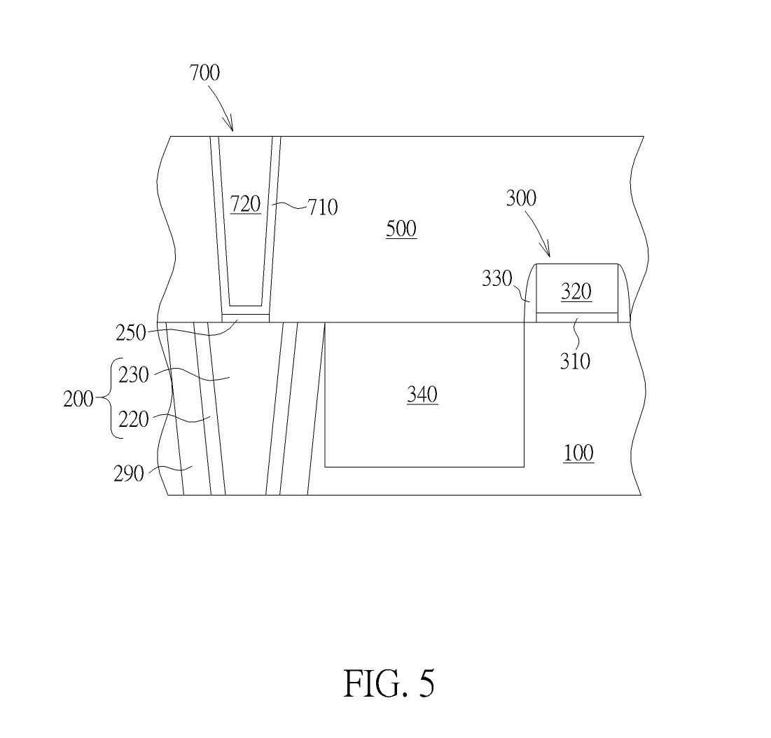

In the following, please referring to FIGS. 4-5, which are schematic drawings illustrating the functions of the CMOS image sensor device. It is noteworthy that when the voltage bias (either a negative voltage bias or a positive voltage bias) applied to the deep trench isolation 200 is greater than the threshold voltage (Vth), an interface region 270 or 290 may be formed accordingly to improve the dark current issues. Precisely, as shown in FIG. 4, when the negative voltage bias is applied, electron-hole may generate and accumulate around the deep trench isolation 200 immediately, thereby performing the interface region 270 adjacent thereto. Such interface region 270 may perform like a hole accumulation layer to protect the sidewalls of the deep trench isolation 200, so that the current leakage issues, as well as the surface defects resulting from forming processes may be fully prevented and thus the dark currents caused by the surface defects may also be reduced accordingly. On the other hand, as shown in FIG. 5, when the positive voltage bias is applied, the interface region 290 may be formed accordingly to configure as a depletion layer, thereby performing a greater depletion region between the photodiode 340 and the deep trench isolation, so as to further improve the image lag issues.

In summary, the CMOS image sensor device of the present invention is formed to include a deep trench isolation which also functions as a depletion transistor. Thus, through controlling the voltage bias applied to the deep trench isolation, the deep trench isolation may optionally perform a hole accumulation layer or a depletion layer accordingly, and therefore, the dark currents resulting from the defected surface, as well as image lag and white pixel issues may be all obviously reduced.

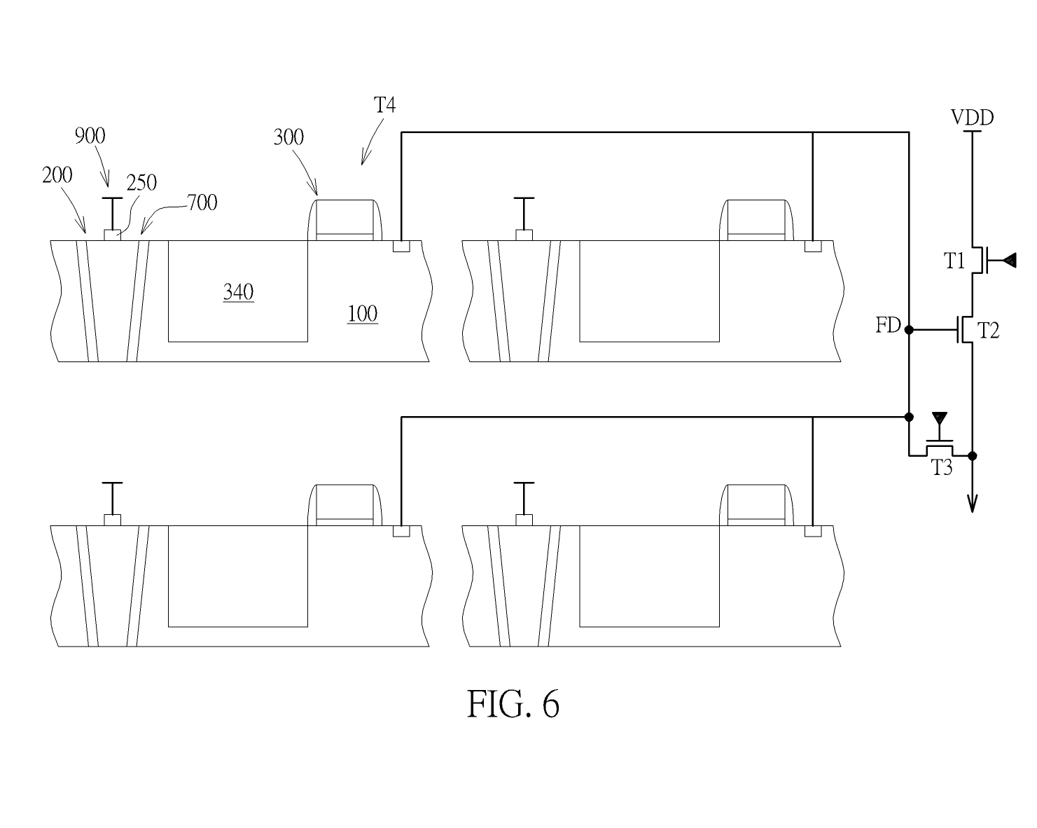

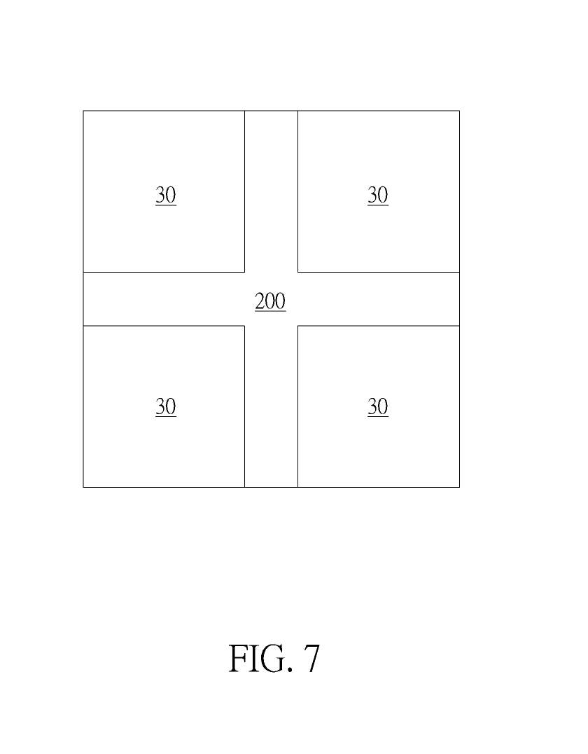

Next, please refer to FIGS. 6-7, which are schematic diagrams illustrating a preferably layout of a CMOS image sensor device in accordance with one embodiment of the present invention, wherein FIG. illustrates a preferably arrangement of pixels, and FIG. 7 illustrates a top view of a practical layout of the deep trench isolation 200 which is according to the pixels. Firstly, as shown in FIG. 7, the deep trench isolation 200 may be formed in the layout shown in FIG. 7, to surround each of the active areas 30, but not limited thereto. Then, referring to FIG. 6, the CMOS image sensor device includes a select transistor T1, a source follower transistor T2, a reset transistor T3, a transfer gate transistor T4, a depletion transistor T5 which is coupled to the transfer gate transistor T4 and a floating diffusion FD formed at a connection point between the transfer gate transistor T4 and the reset transistor T3. Precisely, the floating diffusion node FD may be coupled to a control terminal of the source follower transistor T2, and the source follower transistor T2 is coupled between the power rail VDD and the floating diffusion FD, thereby through the source follower transistor T2 providing a high impedance connection to the floating diffusion FD. Furthermore, the select transistor T1 selectively couples between the power rail VDD and the source follower transistor T2 under control of a select signal SEL, and the reset transistor T3 is coupled between the source follower transistor T2 and the floating diffusion FD to reset the pixel under control of a reset signal.

The depletion transistor T5 includes the deep trench isolation 200 having the dielectric layer 220 formed on an inner surface of the deep trench 210 and the conductive layer 230 filled in the deep trench 210. Wherein the deep trench isolation 200 is electrically connected to the electrode 900 via the ohmic contact 700, such that the deep trench isolation 200 may further perform the depletion layer or the hole accumulation layer at the interface region 270/290 adjacent to the photodiode 340 through controlling the voltage bias applied by the electrode 900.

Furthermore, in one embodiment, the ohmic contact 700 includes the barrier layer 710 and the conductive layer 720, and the barrier layer 710 may include a single layer or a multilayer structure made of titanium (Ti), tantalum (Ta), tantalum nitride (TaN), titanium nitride (TiN) or other suitable materials, and the conductive layer 720 may include tungsten, aluminum or copper, but not limited thereto. In another embodiment, there is the silicide layer 250 between the ohmic contact 700 and the conductive layer 230 of the deep trench isolation 200 for providing preferably electrically connection.

In one embodiment the deep trench isolation 200 may further include a doped region (not shown in the drawings) in the interface region 270/290, having dopant in a different conductive type from that of the photodiode 340, for example, if the photodiode 340 is in N type, the doped region may be in P type.

Those skilled in the art will readily observe that numerous modifications and alterations of the device and method may be made while retaining the teachings of the invention. Accordingly, the above disclosure should be construed as limited only by the metes and bounds of the appended claims.

1. A complementary metal oxide semiconductor (CMOS) image sensor device, comprising:
a substrate;
a deep trench isolation (DTI) disposed in the substrate;
a photodiode disposed in the substrate;
an electrode disposed on the DTI;
an interface region adjacent to the DTI; and
a doped region disposed between the DTI and the photodiode in the interface region, wherein the doped region has a different conductive type from that of the photodiode.

2. The CMOS image sensor device according to claim 1, wherein the DTI is disposed in a deep trench in the substrate, and the DTI comprises a dielectric layer disposed on an inner surface of the deep trench and a conductive layer filled in the deep trench.

3. The CMOS image sensor device according to claim 2, wherein the conductive layer comprises metal or polysilicon.

4. The CMOS image sensor device according to claim 2, wherein the dielectric layer comprises silicon oxide.

5. The CMOS image sensor device according to claim 2, wherein the electrode is electrically connected to the conductive layer of the DTI.

6. The CMOS image sensor device according to claim 2, wherein the deep trench isolation penetrates through a top surface and a bottom surface of the substrate, and a portion of the conductive layer and a portion of the dielectric layer is exposed from a bottom surface of the substrate.

7. The CMOS image sensor device according to claim 2, further comprises an ohmic contact between the electrode and the conductive layer.

8. The CMOS image sensor device according to claim 7, further comprising a silicide layer between the ohmic contact and the conductive layer.

9. The CMOS image sensor device according to claim 7, further comprising an interlayer dielectric layer disposed on the substrate, wherein the ohmic contact is disposed in the interlayer dielectric layer.

10. The CMOS image sensor device according to claim 1, wherein the interface region comprises a hole accumulation layer while the electrode provides a first voltage bias.

11. The CMOS image sensor device according to claim 1, wherein the interface region comprises a depletion layer while the electrode provides a second voltage bias.

12. The CMOS image sensor device according to claim 1, wherein the photodiode has a different conductive type from that of the substrate.

13. (canceled)

14. A method of forming a CMOS image sensor device, comprising:
providing a substrate;
forming a deep trench isolation (DTI) in the substrate;
forming a photodiode in the substrate;
forming an electrode on the DTI;
forming an interface region adjacent to the DTI; and
forming a doped region between the DTI and the photodiode in the interface region, wherein the doped region has a different conductive type from that of the photodiode.

15. The method of forming a CMOS image sensor device according to claim 14, wherein the forming of the DTI comprising:
forming a deep trench in the substrate;
forming a dielectric layer on an inner surface of the deep trench; and
forming a conductive layer on the dielectric layer in the deep trench.

16. The method of forming a CMOS image sensor device according to claim 15, further comprising:
forming an ohmic contact between the conductive layer and the electrode, to electrically connect the conductive layer and the electrode.

17. The method of forming a CMOS image sensor device according to claim 16, further comprising:
forming an interlayer dielectric layer on the substrate, and the ohmic contact is formed in the interlayer dielectric layer.

18. The method of forming a CMOS image sensor device according to claim 16, further comprising:
forming a silicide layer between the ohmic contact and the conductive layer.

19. (canceled)

20. The method of forming a CMOS image sensor device according to claim 14, further comprising:
performing a thinning process from a bottom surface of the substrate to thin the substrate, thereby making the deep trench isolation penetrating through a top surface and the bottom surface of the substrate.
